(19) United States
(12) Patent Application Publication
(10) Pub. No.: US 2010/0176475 A1
(43) Pub. Date: Jul. 15, 2010

(54) OPTICAL DEVICE AND METHOD FOR FABRICATING THE SAME

(75) Inventors: Hikari Sano, Hyogo (JP); Yoshihiro Tomita, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/649,524

(22) Filed: Dec. 30, 2009

(30) Foreign Application Priority Data
Jan. 9, 2009 (JP) 2009-004084

(51) Int. Cl. H01L 31/0232; H01L 31/0216; H01L 31/18

(52) U.S. Cl. 257/432; 257/435; 438/69; 257/E31.127; 257/E31.113; 257/E31.121

(57) ABSTRACT

An optical device according to an aspect of the present invention includes: a semiconductor substrate layer including a plurality of elements; at least one optical component which is formed at the first principal surface side of the semiconductor substrate layer and transmits incident light of desired wavelength; and an interconnect layer formed on second principal surface of the semiconductor substrate layer. In the semiconductor substrate layer, (i) a photoelectric conversion element region is formed at a position corresponding to the at least one optical component, and (ii) at least one element among the plurality of elements is formed near the second principal surface. At least a part of the at least one optical component is formed as a part of the semiconductor substrate layer, and the interconnect layer includes the conductive material electrically connected to the photoelectric conversion element region and the at least one element.

### BACKGROUND OF THE INVENTION

(1) Field of the Invention

The present invention relates to optical devices and a method for fabricating the optical devices. More specifically, the present invention relates to optical devices in which semiconductor elements that are used in digital cameras, mobile phones and the like, imaging elements, light receiving elements such as photo ICs, or light emitting elements such as LED and laser are formed, and to a method for fabricating the optical devices.

(2) Description of the Related Art

In recent years, demand for higher packaging density for semiconductor devices is increasing as well as demand for reduction in size, thickness, and weight of electronic devices. Furthermore, coupled with highly integrated semiconductor elements due to development of microfabrication technique, a so-called chip packaging technique has been proposed in which chip size package or bare chip semiconductor elements are directly packaged.

For example, a backside illuminated image sensor has been proposed which receives light through the back side of a photoelectric conversion element in a semiconductor imaging element (for example, see Japanese Unexamined Patent Application Publication No. 2003-031785). Such a backside illuminated image sensor receives light through the rear side (back side) of a thinned silicon substrate, performs signal processing on signal charge obtained through photoelectric conversion in the silicon substrate, and outputs the processed signal. The backside illuminated image sensor receives light through the back side of the silicon substrate. This allows not only improvement of flexibility in interconnects laminated or packaged on the silicon substrate, but also application of a microfabrication process. Further, the backside illuminated image sensor can include pixels with high aperture ratio without being influenced by interconnects. Here, the aperture ratio refers to index indicating the ratio of the region where light is received in a single pixel. It is possible to transmit light more efficiently as the aperture ratio increases.

FIG. 10 is a diagram showing an example of a cross-sectional structure of a conventional optical device.

An optical device 810 shown in FIG. 10 is a backside illuminated imaging element of, for example, a CMOS image sensor. As shown in FIG. 10, the optical device 810 includes: a semiconductor substrate layer 811; a N− type region 822; a photoelectric conversion element 823; a N+ type region 824; a P+ region 825; a pixel isolation region 826; a shallow P+ layer 827; a transfer transistor 828; a FD 829; a P− layer 830; a MOSFET 831; a P well 832; a NMOS 833; a PMOS 834; a light blocking film 837; a color filter 838; a microlens 839; metal interconnects 840; an insulating layer 848; and a substrate support material 849. Further, the optical device 810 includes the insulating layer 848 formed on a first surface 811a of the semiconductor substrate layer 811, and an interconnect layer 816 and the substrate support material 849 formed below a second surface 811b of the semiconductor substrate layer 811. The optical device 810 can be functionally classified into an optical element integrated region 912 where optical elements are integrated to serve as a pixel unit, and a peripheral circuit region 913 where peripheral circuits are integrated.

Here, the FD refers to floating diffusion, and the MOSFET refers to metal oxide semiconductor field effect transistor. Further, the NMOS refers to negative channel metal oxide semiconductor, and the PMOS refers to positive channel metal oxide semiconductor.

The semiconductor substrate layer 811 is made of silicon (Si) as a base material, for example, having a thickness ranging from 10 to 20 μm approximately. The semiconductor substrate layer 811 includes the photoelectric conversion element 823, the N+ type region 824, the P+ region 825, the pixel isolation region 826, the FD 829 and the P− layer 830 in the optical element integrated region 912 which will serve as a pixel unit. Further, the semiconductor substrate layer 811 includes the N− type region 822 and the P well 832 in the peripheral circuit region 913.

It should be noted that the well structure of the semiconductor substrate layer 811 shown in FIG. 10 is an example of the case where a N− type Si substrate is used.

The interconnect layer 816 is formed on the second surface 811b of the semiconductor substrate layer 811. Further, in the interconnect layer 816, gate electrodes, contact electrodes, and the metal interconnects 840 of the transistors are embedded. More specifically, the gate electrodes, the contact electrodes, and the metal interconnects 840 of the NMOS 833, the PMOS 834, the transfer transistor 828 and the MOSFET 831 are embedded in the interconnect layer 816.

Further, the interconnect layer 816 has a multilevel interconnect structure similar to the structure formed by CMOS process in which metal interconnects having Al or Cu as major component is formed in an insulating film such as a tetra-ethyl-ortho-silicate (TEOS) film.

The substrate support material 849 is formed on the interconnect layer 816 (below the interconnect layer 816 in the figure).

The insulating layer 848 is formed on the first surface 811a of the semiconductor substrate layer 811, and includes an insulating film 848a, the light blocking film 837, and a protective film 848b that are laminated from the bottom in the described order.

The insulating film 848a is made of, for example, silicon dioxide (SiO₂) film. On the insulating film 848a, the light blocking film 837 is formed.

The light blocking film 837 is formed on the insulating film 848a. In other words, the light blocking film 837 is formed so as to sandwich the insulating film 848a with the first surface 811a of the semiconductor substrate layer 811. The light blocking film 837 is made of a metal film having high light blocking properties. Further, the light blocking film 837 includes an opening 837a in the optical element integrated region 912.

The protective film 848b is formed on the light blocking film 837, and is, for example, made of silicon nitride (SiN) film.

The color filter 838 and the microlens 839 are formed above the protective film 848b and at a position corresponds to the opening 837a of the light blocking film 837. Here, the color filter 838 is generally made of color resist, and the microlens 839 is generally made of acrylic resin.

The photoelectric conversion element 823 is formed in the optical element integrated region 912 of the semiconductor substrate layer 811 which will serve as a pixel unit. An example of the photoelectric conversion element 823 is a photodiode.

In the semiconductor substrate layer 811, the photoelectric conversion element 823 includes: the photoelectric conversion region 822a which is made of the N− type region and does not include P well; the P+ region 825 formed at the second surface 11b side of the semiconductor substrate layer 811; and the N+ type region 824 where signal charges are accumulated and which is located between the photoelectric conversion region 822a and the P+ region 825. Further, the photoelectric conversion element 823 is isolated by the pixel isolation region 826 where a deep P well is formed, and is connected to the shallow P+ layer 827 which is formed along the entire first surface 11a of the semiconductor substrate layer 811 in the optical element integrated region 912.

The signal charge, accumulated in the N+ region 824 by the photoelectric conversion element 823, is transferred to the FD 829 in the N+ type region by the transfer transistor 828. Here, the photoelectric conversion element 823 and the FD 829 are electrically isolated by the P− layer 830.

Here, the photoelectric conversion region 822a is formed at a position corresponding to the opening 837a of the light blocking film 837. Further, at the second surface 811b side in the interconnect layer 816, general MOSFET 831 as described above is formed. In addition, constituent transistors of a unit pixel other than the transfer transistor 828, such as an amplifier transistor, an address transistor, and a reset transistor are formed.

Further, in the peripheral circuit region 913, at the second surface 811b side of the semiconductor substrate layer 811, a P well 832 is formed, and a N well is formed in the P well 832. The P well 832 includes a CMOS circuit made of the NMOS 833 and the N well includes a CMOS circuit made of the PMOS 834.

As described, the optical device 810 of, for example, CMOS image sensor shown in FIG. 10 has a backside illuminated pixel structure which receives incident light through the first surface 811a of the semiconductor substrate layer 811 that is opposite to the interconnect layer 816. More particularly, the optical device 810 has a pixel structure where light to be entered from above the microlens 839 is collected by the microlens 839, only light with a desired wavelength is transmitted through the color filter 838, and the transmitted light is lead, through the opening 837a, to the photoelectric conversion region 822a of the photoelectric conversion element 823 that is a photodiode formed in the semiconductor substrate layer 811.

Next, a process for fabricating the optical device 810 having the above structure is described with reference to FIG. 11A to FIG. 11D, and FIG. 12E to FIG. 12H.

FIG. 11A to FIG. 11D and FIG. 12E to FIG. 12H are cross-sectional diagrams for showing a method for fabricating conventional optical devices.

First, element isolation and gate electrode are formed in the semiconductor substrate layer 811 made of the N− type Si substrate. In addition, by ion implantation, the above described shallow P+ layer 827, the deep P well in the pixel isolation region 826, the P well 832 in the peripheral circuit region 913 and the N well in the P well 832 are formed. Further, the active region of the photoelectric conversion element 823 which will serve as a photodiode, and elements such as transistors are formed (FIG. 11A). Note that the process in FIG. 11A is the same as the process of a conventional CMOS image sensor.

Next, the interconnect layer 816 is formed on the semiconductor substrate layer 811. The interconnect layer 816 is made of one or more layers, and has the metal interconnects 840 embedded in the interlayer. In the openings of the surface layer of the interconnect layer 816, first electrode pads 818a are formed (FIG. 11B).

Subsequently, a first substrate support material 849a with conductive materials 850 being embedded is formed on the interconnect layer 816. Here, each of the conductive materials 850 is formed in such a manner that one end is electrically connected to the first electrode pad 818a, and the other end is exposed to the surface of the first substrate support material 849a (FIG. 11C). The other end of the conductive material 850 which is exposed to the surface of the first substrate support material 849a serves as a second electrode pad 818b.

Next, in order for protection of the second electrode pad 818b and planarization of the surface thereof while processing the back side of the semiconductor substrate layer 811, a second substrate support material 849b is formed on the second electrode pads 818b and the first substrate support material 849a.

Then, the back side of the semiconductor substrate layer 811 is processed. More specifically, the back side of the semiconductor substrate layer 811 is polished by chemical mechanical polishing (CMP) till the semiconductor substrate layer 811 is reduced in thickness to 10 μm approximately so that the shallow P+ layer 827 is exposed to the surface (FIG. 12E).

Subsequently, on the backside surface of the semiconductor substrate layer 811 which has been processed, the insulating layer 848, that is, the insulating film 848a, the light blocking film 837, and the protective film 848b are formed (FIG. 12F).

Next, using the same method used in the case of the conventional CMOS image sensor, the color filters 838, the microlenses 839 are formed on the protective film 848b (FIG. 12G).

Next, openings are formed in the portions of the second substrate support 849b corresponding to the second electrode pads 818b so that the second electrode pads 818b are exposed (FIG. 12H).

In such a manner, the optical device 810 is formed.

In general, an optical device, in which optical elements such as imaging elements are formed, has an optical system such as lenses for leading light path to desired direction, color filters for transmitting only light with desired wavelength, and a light blocking structure. For example, in the case where the optical device is an imaging element, it is general that acrylic resin whose shape has been processed is used for a microlens, and a color resist is used for a color filter.

However, in the case where the optical device is made of an organic based material, a high temperature process cannot be applied due to insufficient heat resistance. Further, there is concern that functional capability of the optical device deteriorates over time. Furthermore, there is also a problem of difficulty of high-precision pattern formation along with highly miniaturized pixels.

In order to solve such problems, various structures such as a color filter and a microlens made of an inorganic material have been proposed. In such a case, the optical device 810, such as a backside illuminated imaging element, has an optical path at the opposite side of the interconnect layer 816. This eliminates the need for considering the effects of the interconnect layer 816. Thus, flexibility in design of optical system is relatively high.

However, the optical device 810 such as a backside illuminated imaging element, requires a process in which the semiconductor substrate layer 811 is thinned to a desired thickness, after forming the semiconductor substrate layer 811 and the interconnect layer 816. Therefore, there is concern that the elements and interconnects can be easily damaged in the thinning process, which adversely affecting the optical device properties.

Further, for the optical device 810, in order to maintain the substrate strength in the processes subsequent to the thinning process, it is necessary to bond the substrate support 849 onto the interconnect layer 816; and thus, the first electrode pads 818a on the interconnect layer 816 are covered with the support substrate. As a result, a process is required for establishing conduction between external terminals and the first electrode pads 818a. Accordingly, a process of forming the external terminals becomes complicated.

The present invention is conceived to solve the above problems, and has an object to provide optical devices in which reliability of optical properties are improved with simple processes, and methods for fabricating the optical devices.

### SUMMARY OF THE INVENTION

In order to achieve the above object, the optical device according to an aspect of the present invention includes: a semiconductor substrate layer including a plurality of elements; at least one optical component formed at a first principal surface side of the semiconductor substrate layer; and an interconnect layer formed on a second principal surface of the semiconductor substrate layer and including a conductive material, the second principal surface being an opposite side of the first principal surface side. In the semiconductor substrate layer, (i) a photoelectric conversion element region is formed at a position corresponding to at least one optical component such that the photoelectric conversion element region extends from a second principal surface side toward a first principal surface of the semiconductor substrate layer, and (ii) at least one element among the plurality of elements is formed near the second principal surface. In the semiconductor substrate layer, at least a part of the at least one optical component is formed as a part of the semiconductor substrate layer, and the interconnect layer includes the conductive material electrically connected to the photoelectric conversion element region and the at least one element.

With this structure, it is possible to achieve the optical device in which reliability of optical properties can be improved with simple processes.

More specifically, the optical device according to an aspect of the present invention includes an optical component formed as a part of the semiconductor substrate layer. Thus, it is possible to form an optical component which can be easily miniaturized, has a high heat resistance, and does not easily deteriorate over time. For example, in the case where the optical device is a backside illuminated solid-state imaging device, it is required to provide an optical component such as a microlens and a color filter for each imaging element formed in the semiconductor substrate layer. In order to achieve high resolution, integration level of the imaging elements may be increased. Thus, application of more precise diffusion process is expected for the backside illuminated solid-state imaging device which is not influenced by the interconnect layer. Therefore, it is also necessary to miniaturize the optical components according to the integration level of the imaging elements.

In the optical device according to an aspect of the present invention, by forming an optical component as a part of a semiconductor substrate layer, high-precision patterning for the optical component required along with miniaturization can also be easily performed.

Furthermore, by forming the optical component as a part of the semiconductor substrate layer, it is possible to form the optical component having heat resistance against temperature that is comparable to process temperature in an element formation process. Thus, even after the formation of the optical component, a high temperature process can be applied. Therefore, it is possible to perform, after the formation process of the optical component, element formation process or film formation process that involves high temperature. More specifically, it is possible to achieve an optical device which is highly reliable and resistant to deterioration over time associated with environmental factors such as light degradation or moisture resistance.

Further, the optical component may be a lens having a curved surface which corresponds to a desired wavelength.

Further, the optical component may be a color filter formed by introducing an ionic group so that the color filter corresponds to a desired wavelength.

Further, the optical component may be a color filter in which a minute level difference from the first principal surface is formed, and a thin layer is formed in a space formed by the minute level difference so that the color filter corresponds to a desired wavelength.

Further, the optical component may be a lens formed by introducing an ionic group corresponding to a desired wavelength so that parabolic concentration gradient is established in a concentric pattern.

Further, the optical component may be a color filter having an uneven surface on which minute recesses are formed at spaced intervals so that the color filter corresponds to a desired wavelength.

Further, the optical component may be a lens having an uneven surface on which minute recesses are formed at spaced intervals in a concentric pattern so that the lens corresponds to a desired wavelength. Here, the width of the recesses and the spaced intervals may be narrower as the recesses and the spaced intervals are farther outward from the center of the concentric pattern. The height of the recesses may be smaller as the recesses are farther outward from the center of the concentric pattern.

Further, it may be that the optical device includes an optical element integrated region in which the photoelectric conversion element region and the at least one element are integrated, and a trench is formed in the semiconductor substrate layer at a position closer to the first principal surface, the trench blocking light in a boundary region between adjacent ones of the at least one optical component in the optical element integrated region.

Further, the optical device may further include a light blocking structure formed in at least a region of the interconnect layer corresponding to each of the at least one optical component.

With this structure, it is possible to achieve the optical device in which reliability of optical properties can be improved with simple processes.

In particular, the optical device according to an aspect of the present invention includes a light blocking structure in the interconnect layer.

This allows formation of light blocking structure by the diffusion process; and thus, packaging with consideration of light blocking effect is not necessary. Accordingly, flexibility in selection of implementation is possible.

Further, it is possible to improve capability of detecting defects in optical properties at an intermediate test which is performed at a wafer level. This allows omission of inspection or packaging of the defective devices after being separated into pieces, thereby improving productivity.

Here, it may be that the optical device further includes an optical element integrated region in which the photoelectric conversion element region and the at least one element are integrated, and the light blocking structure is made of a light blocking film corresponding to the optical element integrated region or to each of regions obtained by horizontally dividing the optical element integrated region. The light blocking structure may be made of a structural material identical to a structural material of the conductive material.

Further, the interconnect layer may have a multilayer interconnect structure in which interlayer films are laminated. The light blocking structure may be made of a light blocking film which is made of the conductive material formed in the two or more interlayers among the multilayer interconnect structure.

Here, the light blocking structure may be made of a light blocking film formed at a position corresponding to the photoelectric conversion element region, the light blocking film having an occupied area equal to or larger than an occupied area of the photoelectric conversion region in a horizontal direction. Alternatively, it may be that the light blocking structure is made of a first light blocking film and a second light blocking film, the first light blocking film being formed at a position corresponding to the photoelectric conversion element region such that an occupied area of the first light blocking film is approximately equal to an occupied area of the photoelectric conversion element region in a horizontal direction, the second light blocking film being formed above a rim of the first light blocking film.

Further, the interconnect layer may have a multilayer interconnect structure in which interlayer films are laminated. It may be that the second light blocking film is formed, among the interlayer films, in an interlayer film different from an interlayer film in which the first light blocking film is formed, and the first light blocking film and the second light blocking film are formed such that the rim of the first light blocking film overlaps a part of the second light blocking film in a positional relationship vertical to the interlayer films

Here, the interconnect layer may have a multilayer interconnect structure in which interlayer films are laminated. It may be that the light blocking structure is made of first light blocking films and second light blocking films, the first light blocking films being formed, among the interlayer films, in an interlayer film different from an interlayer film in which the second light blocking films are formed such that a rim of each of the first light blocking films overlap a part of each of the second light blocking films at a position corresponding to the photoelectric conversion element in a positional relationship vertical to the interlayer films, and an occupied area of each of the first light blocking films and each of the second light blocking films is smaller than an occupied area of the photoelectric conversion element in the horizontal direction in the interlayer films.

Further, it may be that the interconnect layer includes one or more structural films laminated, and at least one of the one or more structural films in the light blocking structure is made of a colored material. Here, the optical device may further include an adhesive layer formed on the first principal surface of the semiconductor substrate layer and an optically transparent substrate which is bonded via the adhesive layer and transmits light. Further, it may be that the optically transparent substrate is made of an inorganic material, and the adhesive layer is made of an inorganic material having major component similar to that of the optically transparent substrate.

Further, in order to achieve the above object, the method for fabricating the optical device according to an aspect of the present invention includes: forming an adhesive layer on the first principal surface of a substrate, and forming a support substrate which supports the substrate via the adhesive layer, the substrate being made of a semiconductor and serving as a base material for the semiconductor substrate layer; forming the semiconductor substrate layer; and forming the interconnect layer including the conductive material on the second principal surface of the semiconductor substrate layer.

Further, it is preferable that the method includes: forming the at least one optical component at the first principal surface side of the substrate before forming the support substrate. It is also preferable that forming the semiconductor substrate layer further includes, at a position corresponding to each of the at least one optical component: forming the photoelectric conversion element region extending from the second principal surface side to the first principal surface of the semiconductor substrate layer; and forming the at least one element near the second principal surface of the semiconductor substrate layer. It is also preferable that in said forming the interconnect layer, the conductive material is formed so as to be electrically connected to the photoelectric conversion element region and the at least one elements, and in said forming the at least one optical component, at least a part of the at least one optical component is formed as a part of the semiconductor substrate layer.

Further, the adhesive layer and the support substrate may be made of an inorganic material.

Further, the support substrate may be an optically transparent substrate which transmits light. Further, one end of the conductive material may be exposed to the surface of the interconnect layer to serve as an electrode pad.

With these, it is possible to achieve a method for fabricating the optical device in which reliability of optical properties can be improved with simple processes.

More particularly, the method for fabricating the optical device according to an aspect of the present invention includes a process for forming elements and interconnects after a thinning process. Therefore, it is possible to reduce damages to the elements and the interconnects in the thinning process. Furthermore, by using an inorganic material for an adhesive layer and the support substrate, a high temperature process can be applied after the thinning process since the inorganic material has a high heat resistance.

Further, by thinning the optically transparent substrate as a support substrate, it is not necessary to separate the support substrate. Therefore, the process can be simplified compared to the conventional process which requires separating the support substrate. Further, since the electrode pads are exposed to the conductive materials, the process for establishing the electric conduction between the electrode pads and the conductive materials can be simplified compared to the conventional process which requires such establishment of electric conduction. Further, since the electrode pads are exposed in the middle of the processes, inspection at the wafer level can also be performed easily.

Further, forming the semiconductor substrate layer may include a thinning process in which a material from the second principal surface of the substrate is removed so that the substrate is thinned to a desired thickness, the second principal surface being opposite to the first principal surface of the substrate. The thinning process may further includes: thinning the substrate by polishing the second principal surface of the substrate using an abrasive; and removing a layer of the second principal surface of the substrate which is damaged through polishing, by a soft etching on a surface which has been polished in said thinning the substrate, so as to expose the second principal surface of the semiconductor substrate layer.

The method may further include forming a well within the substrate and near the first principal surface of the substrate from the first principal surface side of the substrate, before forming the support substrate.

Further, forming the interconnect layer may include forming a light blocking structure in the interconnect layer and at a position closer to the second principal surface of the semiconductor substrate. Further, after forming the interconnect layer, a process may be included for further forming an interconnect layer which is made of one or more stress relief layers and includes other conductive material 20 which electrically connects the conductive material and the external terminal.

According to an aspect of the present invention, it is possible to achieve an optical device in which reliability of optical properties can be improved with simple processes and a method for fabricating such an optical device.

More particularly, the optical device according to an aspect of the present invention includes: an optical component formed as a part of the semiconductor substrate layer at the first principal surface side of the semiconductor substrate layer; and a light blocking structure at the second principal surface side of the semiconductor substrate layer. Further, the method for fabricating the optical device according to an aspect of the present invention includes: forming the support substrate at the first principal surface side of the semiconductor substrate layer; thinning the semiconductor substrate layer to a desired thickness by removing a material from the second principal surface of the semiconductor substrate; and forming elements and the interconnect layer at the second principal surface side of the semiconductor substrate layer. With these, it is possible to achieve a small and slim optical device with excellent optical properties and a high functionality. Further, simplification and improved reliability of the processes are possible, thereby achieving a reliable optical device with reduced tact time and low cost.

### FURTHER INFORMATION ABOUT TECHNICAL BACKGROUND TO THIS APPLICATION

The disclosure of Japanese Patent Application No. 2009-004084 filed on Jan. 9, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 illustrates an example of a schematic cross-sectional structure of an optical device according to an embodiment of the present invention;

FIG. 2 illustrates a partial cross-sectional structure of essential parts of the optical device according to an embodiment of the present invention;

FIG. 3A illustrates an example of a partial cross-sectional view of the optical component according to an embodiment of the present invention;

FIG. 3B illustrates an example of a partial cross-sectional view of the optical component according to an embodiment of the present invention;

FIG. 3C illustrates an example of a partial cross-sectional view of the optical component according to an embodiment of the present invention;

FIG. 4 illustrates another example of a partial cross-sectional structure of essential parts of the optical device according to an embodiment of the present invention;

FIG. 5A illustrates an example of a partial cross-sectional view of a light blocking structure formed in the optical device according to an embodiment of the present invention;

FIG. 5B illustrates an example of a partial cross-sectional view of a light blocking structure formed in the optical device according to an embodiment of the present invention;

FIG. 6A is a cross-sectional view showing an example of a method for fabricating the optical device according to an embodiment of the present invention;

FIG. 6B is a cross-sectional view showing an example of a method for fabricating the optical device according to an embodiment of the present invention;

FIG. 6C is a cross-sectional view showing an example of a method for fabricating the optical device according to an aspect of the present invention;

FIG. 6D is a cross-sectional view showing an example of a method for fabricating the optical device according to an embodiment of the present invention;

FIG. 7E is a cross-sectional view showing an example of a method for fabricating the optical device according to an embodiment of the present invention;

FIG. 7F is a cross-sectional view showing an example of a method for fabricating the optical device according to an embodiment of the present invention;

FIG. 7G is a cross-sectional view showing an example of a method for fabricating the optical device according to an embodiment of the present invention;

FIG. 7H is a cross-sectional view showing an example of a method for fabricating the optical device according to an embodiment of the present invention;

FIG. 8 is a cross-sectional view illustrating an example of an implementation of the optical device according to an embodiment of the present invention;

FIG. 9A is a schematic diagram illustrating an example of a system including the optical device according to an embodiment of the present invention;

FIG. 9B is a schematic diagram illustrating an example of a system including the optical device according to an embodiment of the present invention;

FIG. 10 illustrates an example of a cross-sectional structure of a conventional optical device;

FIG. 11A is a cross-sectional view showing a method for fabricating a conventional optical device;

FIG. 11B is a cross-sectional view showing a method for fabricating the conventional optical device;

FIG. 11C is a cross-sectional view showing a method for fabricating the conventional optical device;

FIG. 11D is a cross-sectional view showing a method for fabricating the conventional optical device;

FIG. 12E is a cross-sectional view showing a method for fabricating the conventional optical device;

FIG. 12F is a cross-sectional view showing a method for fabricating the conventional optical device;

FIG. 12G is a cross-sectional view showing a method for fabricating the conventional optical device; and

FIG. 12H is a cross-sectional view showing a method for fabricating the conventional optical device.

### DESCRIPTION OF THE PREFERRED EMBODIMENT(S)

Hereinafter, an optical device and a method for fabricating the optical device according to an embodiment of the present invention are specifically described with reference to the drawings. Here, an example of a backside illuminated imaging element is described; however, the present invention can be applied to various kinds of optical devices as long as not departing from the principles of the present invention. It is to be noted that same numerical references are assigned to same elements in the drawings. For simplification, duplicate descriptions of the same elements may be omitted. It is also to be noted that the drawings schematically show elements mainly for facilitating understanding; and thus the shape and the like are not shown accurately.

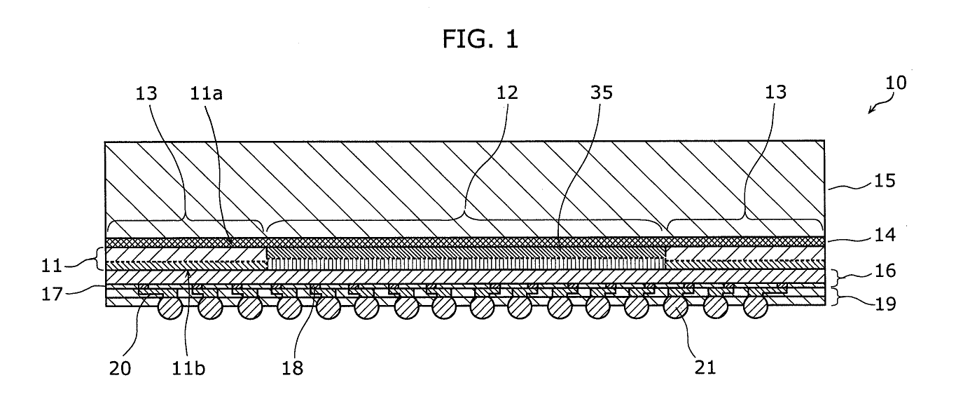

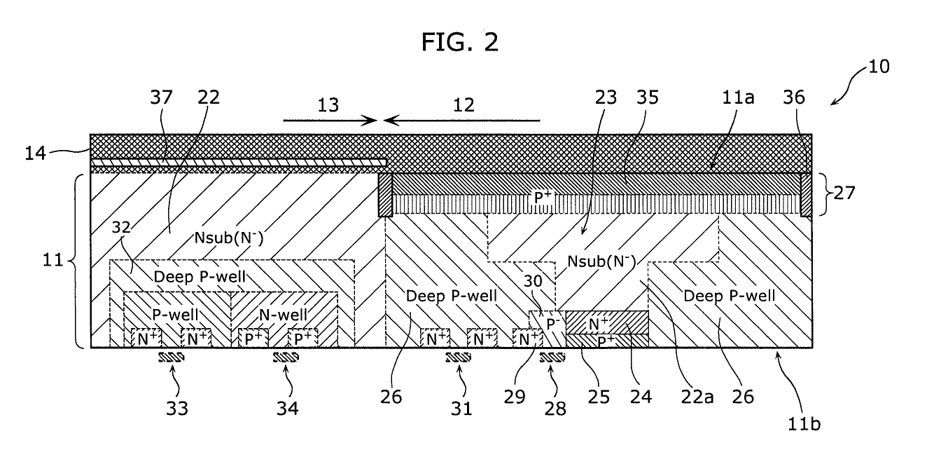

FIG. 1 illustrates an example of a schematic cross-sectional structure of an optical device according to an embodiment of the present invention. FIG. 2 illustrates a partial cross-sectional structure of essential parts of the optical device according to an embodiment of the present invention. An optical device 10 shown in FIG. 1 is, for example, a backside illuminated imaging element. The optical device 10 is functionally divided into an optical element integrated region 12 where optical elements are integrated to serve as a pixel unit, and peripheral circuit regions 13 where peripheral circuits are integrated.

As shown in FIG. 1 and FIG. 2, the optical device 10 includes: a semiconductor substrate layer 11; an adhesive layer 14; an optically transparent substrate 15; an interconnect layer 16; an interconnect layer 19; conductive materials 20; external terminals 21; N− type regions 22; photoelectric conversion elements 23; N+ regions 24; P+ regions 25; pixel isolation regions 26; a shallow P+ layer 27; transfer transistors 28; FDs 29; a P− layer 30; MOSFETs 31; P wells 32; NMOSs 33; PMOSs 34; and optical components 35. Further, it is preferable to include a trench 36 at the isolation border of the unit pixels.

As shown in FIG. 1, the optical device 10 includes the optical element integrated region 12 and the peripheral circuit regions 13. The semiconductor substrate layer 11 includes, at the first surface 11a side, the optical components 35, such as a microlens, color filter and light blocking structure. On the other hand, the optical device 10 includes the interconnect layer 16 formed on the second surface 11b of the semiconductor substrate layer 11. The interconnect layer 16 is made of one or more insulating layers into which conductive materials electrically connected to the elements formed in the semiconductor substrate layer 11 are embedded.

The semiconductor substrate layer 11 is made, for example, of a thin silicon (Si) substrate as a base material. It is desirable to optimize thickness of the semiconductor substrate layer 11 according to desired wavelength of light. The suitable thickness is approximately ranging from a few μm to 50 μm. The semiconductor substrate layer 11 includes the photoelectric conversion element 23, the N+ region 24, the P+ region 25, the pixel isolation region 26, the FD 29 and the P− layer 30 in the optical element integrated region 12 which will serve as a pixel unit. Further, the semiconductor substrate layer 11 includes the N− type region 22 and the P well 32 in the peripheral circuit region 13.

It should be noted that the well structure of the semiconductor substrate layer 11 shown in FIG. 1 is an example of the case where a N− type Si substrate is used.

The interconnect layer 16 is formed on the second surface 11b of the semiconductor substrate layer 11. The interconnect layer 16 is made of one or more insulating layers into which conductive materials electrically connected to the elements formed in the semiconductor substrate layer 11 are embedded. The interconnect layer 16 includes: an insulating layer into which gate electrodes, contact electrodes and interconnects of transistors are embedded; and a protective film 17 made of one or more insulating films formed on the insulating layer (below the insulating layer in the figure) and has electrode pads 18 which are the exposed portions of the conductive materials. More specifically, the interconnect layer 16 includes: the insulating layer in which the gate electrodes, the contact electrodes and the interconnects of the NMOS 33, the PMOS 34, the transfer transistor 28, and the MOSFET 31 are embedded; and the protective layer 17 made of the insulating layer having the electrode pads 18.

Further, the interconnect layer 16 is formed using known CMOS processes. For example, SiO₂ is used for a gate oxide film, polysilicon is used for a gate electrode, and W (tungsten) or the like is used for a contact electrode. The interconnects made of Al or Cu as major components are formed in the insulating layer in which one or more TEOS films or fluorinated silica glass (FSG) films are laminated.

The interconnect layer 19 is formed on the interconnect layer 16 (below the interconnect layer 16 in the figure). On the interconnect layer 16 (below the interconnect layer 16 in the figure), external terminals 21 are provided. Further, the interconnect layer 19 includes in one or more stress relief layers, conductive materials 20 which electrically connects the electrode pads 18 and the external terminals 21.

More particularly, the interconnect layer 19 includes interconnects made of conductive materials 20 that include Cu, Al or the like as major components, in the stress relief layers in which one or more resin films such as polyimide based or epoxy based resin films are laminated. For the external terminals 21, solder bumps that include, for example, SnAg or SnAgCu, as major components are used. For the electrode pads 18, Al alloy or the like is used. For the protective film 17 in the interconnect layer 16, SiN films or the like are generally laminated.

The optically transparent substrate 15 is a substrate which transmits light, and is used for sealing, via the adhesive layer 14, the first surface 11a of the semiconductor substrate layer 11 in order to reduce the influences of dusts to the optical device 10. For the optically transparent substrate 15, for example, an optical glass substrate having a thickness ranging from 0.3 to 0.7 mm is used.

For the adhesive layer 14, an acrylic resin film or the like in which refractive index is adjusted, is generally used.

Further, the adhesive layer 14 includes the light blocking film 37 for obtaining desired optical properties and also for preventing the resin film from being optically degraded. The light blocking film 37 includes an opening at the position, in the optical element integrated region 12, corresponds at least to the photoelectric conversion region 22a which will serve as the photoelectric conversion element 23. For the adhesive layer 14, it is preferable to use inorganic materials, such as a glass layer which has excellent heat resistance and no concern for optical degradation, instead of using a resin film, and to bond to the optically transparent substrate 15. For example, after forming an oxide silicon film, the glass substrate can be bonded to the optically transparent substrate 15 with methods such as thermal fusion bonding or alkali bonding.

Here, the light blocking film 37 is formed, in the adhesive layer 14, as a protective film having a light blocking structure. The light blocking film 37 is formed above the first surface 11a of the semiconductor substrate layer 11 and at least in the peripheral circuit region 1. Further, the light blocking film 37 has insulation properties and is formed in a part of the adhesive layer 14. Thus, it is preferable that the light blocking film 37 be made of, for example, a silicon dioxide film. Of course, the light blocking film 37 may be made of a metal film which includes W, Ti, Cu, Al or the like as a primary element and which is formed between inorganic material films such as silicon dioxide films and silicon nitride films that are generally used.

The photoelectric conversion element 23 is, for example, a photodiode. The photoelectric conversion element 23 includes: the photoelectric conversion region 22a which is made of the N− type region and does not include P well; the P+ region 25 formed at the second surface 11b side of the semiconductor substrate layer 11; and the N+ region 24 where signal charges are accumulated and which is located between the photoelectric conversion region 22a and the P+ region 25. Further, the photoelectric conversion element 23 is isolated by the pixel isolation region 26 where a deep P well is formed, and is connected to the shallow P+ layer 27 which is formed along the entire first surface 11a of the semiconductor substrate layer 11 in the optical element integrated region 12.

The signal charge, accumulated in the N+ type region 24 by the photoelectric conversion element 23, is transferred to the FD 29 in the N+ type region by the transfer transistor 28. Here, the photoelectric conversion element 23 and the FD 29 are electrically isolated by the P− layer 30.

Here, elements formed laying across the semiconductor substrate layer 11 and the interconnect layer 16 are described.

In the optical element integrated region 12 of the semiconductor substrate layer 11 and the interconnect layer 16, the transfer transistor 28 and the general MOSFET 31 are formed, and further, constituent transistors of a unit pixel other than the transfer transistor 28, such as an amplifier transistor, an address transistor, and a reset transistor, are formed. On the other hand, in the peripheral circuit region 13, the P well 32 is formed at the second surface 11b side of the semiconductor substrate layer 11. In the P well 32, a P well which includes a MOS circuit made of the NMOS 33 and a N well which includes a MOS circuit made of the PMOS 34 are formed. As described above, the gate oxide film, the gate electrode, the contact electrode and the like of the NMOS 33 and the PMOS 34 are formed at the interconnect layer 16 side.

The optical component 35 transmits incident light with a desired wavelength, and is made as a part of the semiconductor substrate layer 11 at the position which corresponds to at least the photoelectric conversion region 22a at the first surface 11a side of the semiconductor substrate layer 11. Since the optical component 35 is made as a part of the semiconductor substrate layer 11, it is possible to form the optical component 35 which can be easily miniaturized, has a high heat resistance, and does not easily deteriorate over time.

The trench 36 is formed by embedding light blocking material, such as tungsten (W), to the isolation border of the unit pixels in order to prevent obliquely incident light or scattering light from entering the photoelectric conversion element 23 of the adjacent pixel and causing color mixture. Further, in the case where a conductive material, such as tungsten, is used for light blocking material, it is preferable to form an insulating film, such as a silicon dioxide film, on the inner wall of the trench 36, and to electrically isolate the semiconductor substrate layer 11 and the trench 36.

When forming the optical component 35 and the trench 36, it is preferable that a well is formed near the first surface 11a of the semiconductor substrate layer 11 (here, it is preferable to form the shallow P+ layer 27 and the well near the shallow P+ layer 27 of the pixel isolation region 26). It is because when a well is formed at the position relatively shallow from the first surface 11a of the semiconductor substrate layer 11, excellent control of ion implantation can be obtained.

In such a manner, the optical device 10 shown in FIG. 1 and FIG. 2 is formed.

Next, the optical component 35 having the features of an aspect of the present invention is described with examples.

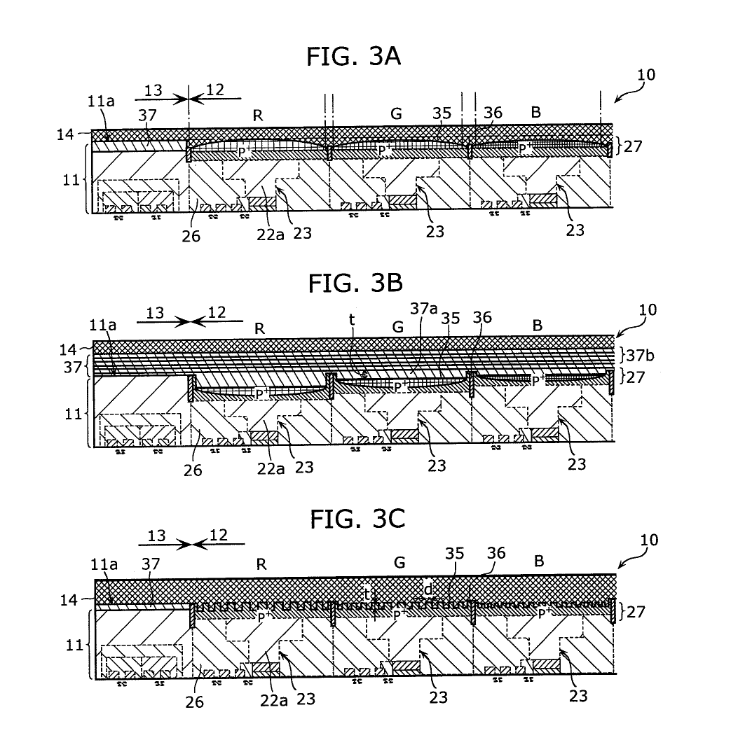

FIG. 3A to FIG. 3C each illustrates an example of a partial cross-sectional view of the optical components according to an embodiment of the present invention. FIG. 3A to FIG. 3C show different implementations of the optical components 35.

Each optical component 35 shown in FIG. 3A is formed as a lens having a desired curved surface at the position which corresponds to the photoelectric conversion region 22a. The optical component 35 is formed by processing the first surface 11a of the semiconductor substrate layer 11. Further, the shallow P+ layer 27 formed at the semiconductor substrate layer 11 side of the optical component 35 is also processed to have a lens shape, that is, a desired curved surface.

For example, in the case where the semiconductor substrate layer 11 is a Si substrate, it is expected that the optical component 35 exhibits high light collect efficiency even though the lens has a gentle curved surface, since the Si has a high refractive index of 3 to 8. Further, light incident upon the pixel isolation region 26 can also be lead to the photoelectric conversion region 22a passing through the lens-shaped shallow P+ layer 27, thereby improving the optical aperture ratio.

The refractive index of Si depends on the wavelength; and thus, it is preferable that the curved surface shape of the lens constituting the optical component 35 is optimized according to the desired wavelength. For example, the refractive index of Si for visible light is ranging from 4 to 7 approximately, and increases in the order of red (R), green (G) and blue (B). Thus, it may be that the thickness of the lens for blue (B) having a higher refractive index can be made smaller than that of the lens for red (R) having a relatively lower refractive index. As a result, desired visible light of light which passes through (incident upon) the optical component 35 can be selectively transmitted. Further, by forming the lens constituting the blue (B) optical component 35 having a high absorption ratio, closer to the photoelectric conversion region 22a, more efficient photoelectric conversion is possible.

Further, it is preferable that the optical component 35 includes a color filter colored by introducing, into the surface of the optical component 35, ionic group corresponding to the desired wavelength.

In such a manner, respective optical components 35 can be formed as a part of the semiconductor substrate layer 11 at the first surface 11a side of the semiconductor substrate layer 11.

Each optical component 35 shown in FIG. 3B is formed as a color filter. The color filter includes, at the position corresponding to the photoelectric conversion region 22a, a minute level difference t formed by processing the first surface 11a of the semiconductor substrate layer 11. The height of the level difference t is approximately same as the desired wavelength, and a thin layer 37a is formed in a space formed by the level difference t.

With the principle of interference of light passing through the thin layer 37a, the color filter constituting the optical component 35 transmits desired visible light by allowing only transmitted light with desired wavelength to strengthen each other.

Here, the optimum value of the level difference t is determined by the desired wavelength and refractive index of the medium of the thin layer 37a. For the color filter constituting the optical component 35, the level difference is formed by directly processing the first surface 11a of the semiconductor substrate layer 11, thereby enhancing flexibility in designing the level difference t. As a result, it is possible for such a color filter to include the level difference t in which the thin layer 37a having a flat surface is formed such that the level difference t has the optimum value for different wavelength.

For example, when the color filters constituting the optical components 35 respectively transmit visible light of red (R), green (G), and blue (B), the height of each level difference t in which the thin layer 37a is formed may be changed according to the wavelength ratio. More specifically, it may be such that the level difference t for the blue (B) with a shorter wavelength is made to be smaller than that for the red (R) with a longer wavelength. Further, it may be that the level difference t smaller than the level difference t of the blue (B) is formed at the isolation border of the unit pixels and in the peripheral circuit region 13 so that obliquely incident light and scattering light can be blocked. Here, the thin layer 37a is only required to be made of, for example, SiO₂.

As described, the thin layer 37a can selectively transmit one of red (R), green (G) and blue (B) at the corresponding level difference t, and can block light at the position where the corresponding level difference t is not formed.

Further, as shown in FIG. 3B, a dielectric multilayer film 37b is further formed on the thin layer 37a. With the dielectric multilayer film 37b, only transmitted light in a desired wavelength range can be strengthened each other, thereby improving spectral properties of the color filter constituting the optical component 35. Here, the dielectric multilayer film 37b is, for example, formed by laminating SiO₂ and TiO₂ to a predetermined thickness in a certain order. Further, the dielectric multilayer film 37b can selectively transmit only light in a certain wavelength range, for example, red (R), green (G), or blue (B), by optimizing the film thickness and the number of layer stacks of SiO₂ and TiO₂.

Note it is preferable that the optical component 35 is a refractive index distribution lens formed by introducing, into the surface of the lens, ionic group corresponding to a desired wavelength so that parabolic concentration gradient is established in a concentric pattern. Further, by varying the refractive index of the medium, light incident upon the pixel isolation region 26 can also be lead to the photoelectric conversion region 22a passing through the shallow P+ layer 27, thereby improving optical aperture ratio.

Accordingly, the optical component 35 can be formed as a part of the semiconductor substrate layer 11 at the first surface 11a side of the semiconductor substrate layer 11.

Note that it is preferable that the shallow P+ layer 27 has a depth optimized according to the level difference t or the absorption ratio of desired wavelength.

Each optical component 35 shown in FIG. 3C has an uneven surface which is formed by processing the first surface 11a of the semiconductor substrate layer 11 and on which minute recesses are formed at spaced intervals. The minute recesses are approximately same as the desired wavelength and formed in the shallow P+ layer 27 which corresponds to the photoelectric conversion region 22a.

With the principle of interference of light due to the optical path difference generated by diffraction and the height of the recesses, the optical component 35 can selectively transmit desired visible light by allowing transmitted light with desired wavelength to strengthen each other. Further, by forming the uneven surface on which the recesses are formed at spaced intervals in a concentric pattern, it is possible for the optical component 35 to collect light with the use of the principle that diffracted light with desired wavelength strengthen each other into a certain direction.

Here, the optimum values of height t of the recesses and the width d of the recesses and the spaced intervals formed in a concentric pattern are determined by the desired wavelength and the difference of refractive index between the medium of the semiconductor substrate layer 11 and the medium embedded into the recesses, such as Si and SiO₂. By making the width d of the concentrically formed recesses and spaced intervals smaller (narrower) as they are further outward from the center of the concentric pattern, it is possible to correct the optical path difference between the center and outward so that the direction into which the transmitted light with desired wavelength strengthen each other can be lead to the center.

Further, by making the height t of the concentrically formed recesses smaller (thinner) as they are further outward from the center of the concentric pattern so as to correct the optical path difference, similar advantageous effects can be expected.

Accordingly, the uneven surface, on which the recesses are formed at spaced intervals, formed in the shallow P+ layer 27 allows light incident upon the pixel isolation region 26 and having desired wavelength to be lead to the photoelectric conversion region 22a. As a result, it is possible to improve optical aperture ratio. This is because the uneven surface, on which the recesses are formed at spaced intervals, formed in the shallow P+ layer 27 limits wavelength which meet requirements for allowing light to strengthen each other into a certain direction, which results in preferentially leading light with a certain wavelength into the photoelectric conversion region 22a. Therefore, under certain conditions, the optical component 35 can collect light and selectively transmit light at the same time.

As described, the optical component 35 can be made as a part of the semiconductor substrate layer 11 at the first surface 11a side of the semiconductor substrate layer 11.

Further, it is preferable that the depth of the shallow P+ layer 27 is optimized according to the position at which desired wavelength strengthen each other. Further, the light blocking film 37, formed at the first surface 11a of the semiconductor substrate layer 11 in the peripheral circuit region 13, may also have an uneven surface on which minute recesses are formed at spaced intervals at the first surface 11a side of the semiconductor substrate layer 11.

Note that optimum shapes of the optical components 35 shown in FIG. 3A to FIG. 3C also depend on incident angle of light. Therefore, it is more preferable to optimize the optical component 35 for each unit pixel in consideration of the angle of light incident upon the position of each unit pixel in the optical element integrated region 12 which will serve as a pixel unit.

Further, the light blocking structure which blocks light at the isolation border of the unit pixels and the light blocking film 37, are generally made of a metal film which includes, for example, W, Ti, Cu, or Al, as a primary element and which is formed between inorganic material films such as silicon dioxide films and silicon nitride films; however, the structure may be made in accordance with the color filter structure of the optical component 35 described above. Here, it is preferable that the topmost layer of the inorganic material films constituting the light blocking structure and the light blocking film 37 is bonded to the optically transparent substrate 15 while serving as the adhesive layer 14.

Further, in order to increase relative refractive index for obtaining desired optical properties, the inorganic material films constituting the light blocking structure and the light blocking film 37 may include an opening at the position which contacts the optical component 35 located at a position which corresponds at least to the photoelectric conversion region 22a in the optical element integrated region 12. In such a case, it is preferable to keep the opening in a vacuumed state or a reduced pressure atmosphere in order to suppress adverse effects imposed by heat expansion of gas inserted into the opening of the inorganic material film.

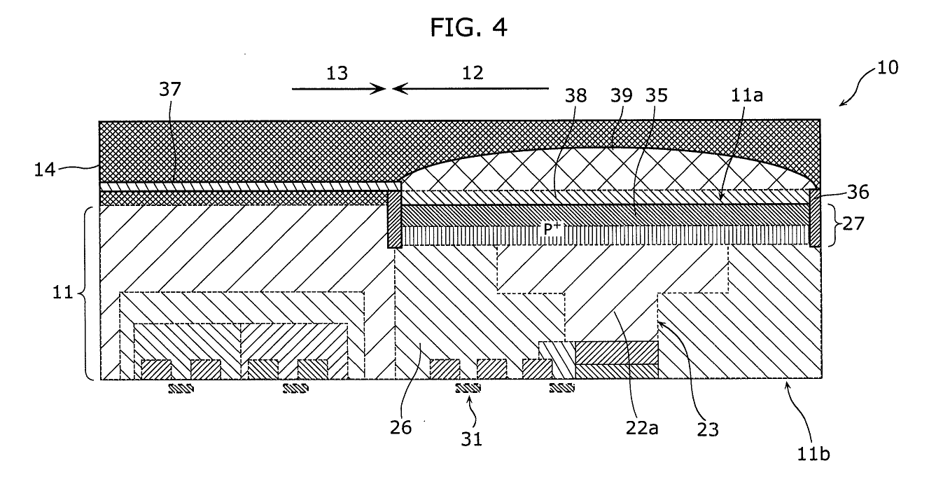

Further, the optical device 10 may include, as shown in FIG. 4, a color filter and a microlens in addition to the optical component 35. Such a case is described with reference to the drawing.

FIG. 4 illustrates another implementation of a partial cross-sectional structure of essential parts of the optical device according to an embodiment of the present invention. Note that the same numerical references are assigned to the same elements appeared in FIG. 1 and FIG. 2, and duplicate descriptions of the same elements are omitted.

As shown in FIG. 4, the optical component 35 is a secondary optical system for improving light collection efficiency or correcting chromatic aberration. The optical component 35 may include the color filter 38 and the microlens 39 at the first surface 11a side of the semiconductor substrate layer 11.

Here, generally, the color filter 38 is made of color resist, and the microlens 39 is made of acrylic resin.

Furthermore, a planarized film (not shown), made of, for example, acrylic resin in which refractive index is adjusted may be formed on the microlens 39.

When forming the optical device 10 shown in FIG. 4, it is preferable to use inorganic material film having excellent heat resistance so that high temperature processes can be applied. For example, a colored SiO₂ film can be used for the color filter 38, and a TiO₂ (transparent material) which has been processed into lens shape can be used for the microlens 39.

Further, in the optical device 10, a planarized film may be further formed on the microlens 39. In such a case, it is preferable that the planarized film is made of inorganic material such as SiO₂ film serving also as the adhesive layer 14.

Further, it is preferable that the trench 36 shown in FIG. 4 and embedded into the isolation border of the unit pixels are formed such that the trench 36 contacts the color separation boundary of the color filters 38, or extends to the color separation boundary, in order to prevent color mixture.

Next, the light blocking structure formed at the second surface 11b side of the semiconductor substrate layer 11 of the optical device 10 according to an embodiment of the present invention, that is, in the interconnect layer 16, will be described with reference to the drawings.

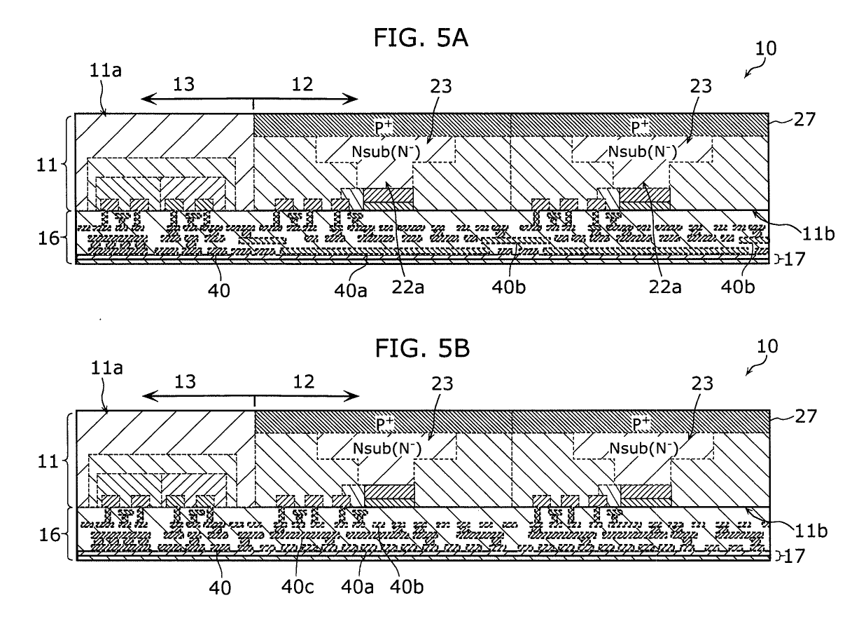

FIG. 5A and FIG. 5B each shows a partial cross-sectional view of an example of a light blocking structure formed in the optical device according to an embodiment of the present invention. Note that same numerical references are assigned to the same elements appeared in FIG. 1 and FIG. 2, and detailed descriptions thereof are omitted.

Each optical device 10 shown in FIG. 5A and FIG. 5B is characterized in inclusion of the light blocking films 40a and the light blocking films 40b which serve as a light blocking structure in the region which corresponds at least to the photoelectric conversion region 22a.

As described, the interconnect layer 16 is formed on the second surface 11b of the semiconductor substrate layer 11, and is made of one or more insulating layers into which conductive materials electrically connected to the elements formed in the semiconductor substrate layer 11 are embedded. Further, the interconnect layer 16 includes, in the insulating layer into which the gate electrodes, the contact electrodes and interconnects of the transistors are embedded, the metal interconnects 40, the light blocking films 40a, and the light blocking films 40b that are shown in FIG. 5A and FIG. 5B.

The light blocking films 40a and the light blocking films 40b are light blocking structure made of conductive materials formed in the region corresponding to the optical element integrated region 12 in the interconnect layer 16.

The metal interconnects 40 are made of conductive materials which electrically connect elements formed in the optical element integrated region 12 and the peripheral circuit region 13 in the interconnect layer 16.

Here, it is preferable that the conductive materials constituting the metal interconnects 40, the light blocking films 40a, and the light blocking films 40b of the interconnect layer 16 are formed during a single process. Further, the conductive materials constituting the light blocking structure of the light blocking films 40a and the light blocking films 40b are, for example, made of metal materials having Al or Cu as a major component. Further, it may be that the conductive materials constituting the light blocking structure are formed as part of the metal interconnects 40 to serve also as electrical connection path.

Further, the light blocking films 40a and the light blocking films 40b may have a three-dimensional light blocking structure in which conductive materials are formed in multiple insulating layers of the interconnect layer 16.

The optical device 10 shown in FIG. 5A includes, for each unit pixel, the light blocking film 40a in the interconnect layer 16. Each light blocking film 40a is formed in a region of the interconnect layer 16 corresponding to the photoelectric conversion region 22a, and has a light blocking structure corresponding to a region which is an equivalent size to the photoelectric conversion region 22a or a size larger than the photoelectric conversion region 22a.

As described, conductive materials are formed so as to cover the optical element integrated region 12 or to each of regions of the optical element integrated region 12 obtained by horizontally dividing the optical element integrated region 12, thereby reducing the effects of film stress. This also allows formation of reliable light blocking films 40a.

Further, as shown in FIG. 5A, the light blocking film 40b is formed between the adjacent light blocking films 40a, as a supplemental light blocking film which assists light blocking of the light blocking film 40a.

For example, light blocking film 40b is formed in one of the insulating layers of the interconnect layer 16 which is on the plane different from the plane on which the light blocking film 40a is formed such that the light blocking film 40b partially overlaps the rim of the light blocking films 40a which are adjacent to the light blocking film 40b in a positional relationship vertical to the insulating layers in FIG. 5A. This ensures light blocking property between the adjacent light blocking films 40a.

The optical device 10 shown in FIG. 5B includes, in the interconnect layer 16, the light blocking films 40a and the light blocking films 40b as a light blocking structure.

The light blocking films 40a and the light blocking films 40b each has a rectangle shape. The light blocking films 40a are formed in one of the insulating layers of the interconnect layer 16 which is on the plane different from the plane on which the light blocking films 40b are formed. Further, the light blocking films 40a and the light blocking films 40b are formed in the region corresponding to the photoelectric conversion region 22a of the interconnect layer 16 such that the rim of the light blocking films 40a overlaps the rim of the light blocking films 40b in a positional relationship vertical to the insulating layers in FIG. 5B.

Accordingly, by arranging the light blocking films 40a and the light blocking films 40b made of a plurality of light blocking films such that they partially overlap with each other in the positional relationship vertical to the insulating layers in FIG. 5B, light blocking property can be ensured. In addition, by making the width of the light blocking film 40a and the light blocking film 40b which are made of a plurality of light blocking films, smaller, it is possible to suppress dishing caused during the planarization process by CMP. Note that the dishing refers to the phenomena that metal interconnects are polished into a plate-like shape, which is one of the problems associated with CMP.

Further, the optical device 10 shown in FIG. 5B includes, between the light blocking films 40a and the light blocking films 40b, metal interconnects 40c which are connected to the light blocking films 40a and the light blocking films 40b. By connecting the light blocking film 40a and the light blocking film 40b with the metal interconnect 40c to form an electrical connection path, it is possible to suppress interconnect constraint due to the light blocking structure.

Note it may be that, as a light blocking structure formed at the second surface 11b side of the semiconductor substrate layer 11 of the optical device 10, colored materials are used for the structural films for the interconnect layer 16, that is, the insulating layer into which the metal interconnects 40 are embedded and the protective film 17. In this case, the protective film 17 may include a light blocking structure formed by a colored inorganic material film, such as a black glass layer, or an organic film colored using dye and pigment. Accordingly, use of the light blocking structural films in the interconnect layer 16 allows flexibility in design of interconnects without constraints in the light blocking structure.

In such a manner described above, the optical device 10 according to an aspect of the present invention is formed. As a result, by forming the light blocking structure at the second surface 11b side of the semiconductor substrate layer 11 of the optical device 10 in the process of forming the interconnect layer 16, it is possible to increase flexibility in implementation of the optical device 10.

For example, in a conventional method, an interconnection substrate having light blocking properties are packaged. This results in imposing constraints on the light blocking conditions in the packaging process. However, the present invention eliminates the constraints imposed on the light blocking conditions in the packaging process, since it is possible to package, for example, a translucent tape material in which interconnects are formed.

Further, with the diffusion process, it is possible to form the light blocking structure of the optical device 10 according to an aspect of the present invention. This improves capability of detecting chips having defects in optical properties, in an intermediate test performed at a wafer level. Detection of defective chips at a wafer level allows omission of inspecting or packaging of the defective chips after being separated into pieces.

Next, a method for fabricating the optical device 10 according to an aspect of the present invention is described.

Note that the optical device 10 according to an aspect of the present invention can be made using a conventional fabricating method. More specifically, the interconnect layer 16 is formed on the second surface 11b of the semiconductor substrate layer 11 having elements in the optical element integrated region 12 and the peripheral circuit region 13. The interconnect layer 16 is made to include the support substrate. After thinning the semiconductor substrate layer 11 of the optical device 10 including the support substrate, the optical component 35 is formed at the first surface 11a side of the thinned semiconductor substrate layer 11. With such processes, the optical device 10 according to an aspect of the present invention is formed. However, as described above, the conventional fabricating method has concerns associated with property deterioration and reliability failure derived from damages generated in the thinning process. Further, in the conventional fabricating method, the electrode pads 18 are covered with the support substrate. This necessitates a process for establishing conduction penetrating the support substrate between the electrode pads 18 and the external terminals 21, and a process for separating the support substrate for exposing the electrode pads 18.

In view of the above problems, the optical device fabricating method according to an aspect of the present invention has an object to provide a method for fabricating the optical device 10 in which reliability of optical properties are improved with simple processes.

Hereinafter, the optical device 10 according to an aspect of the present invention will be described specifically with reference to the drawings. Note that the fabricating method of the optical device 10 according to an aspect of the present invention is not limited to the fabricating method described below.

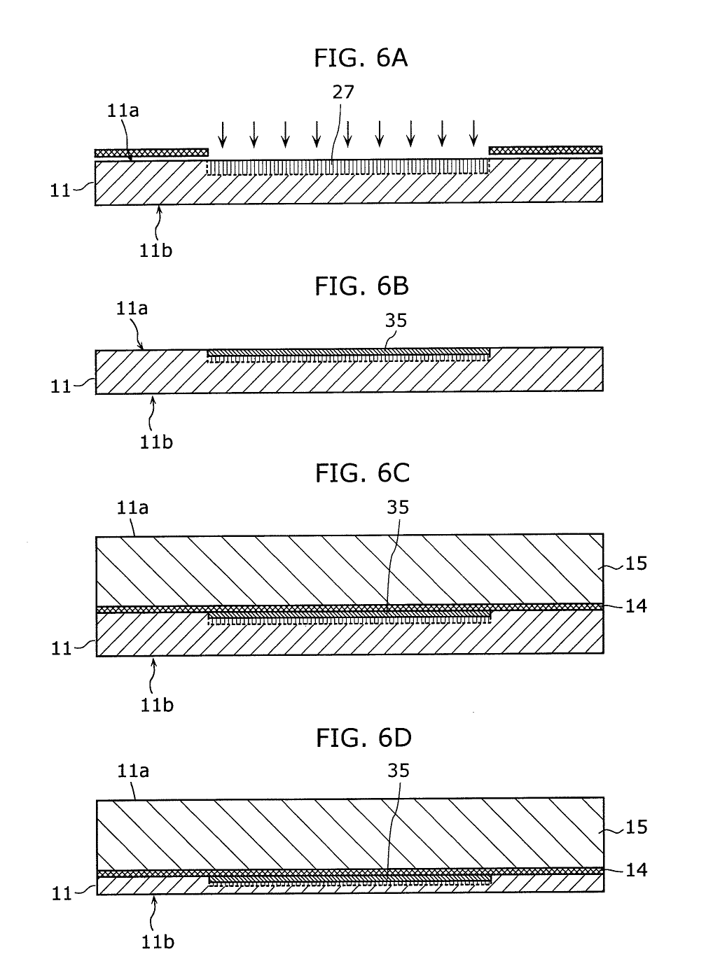

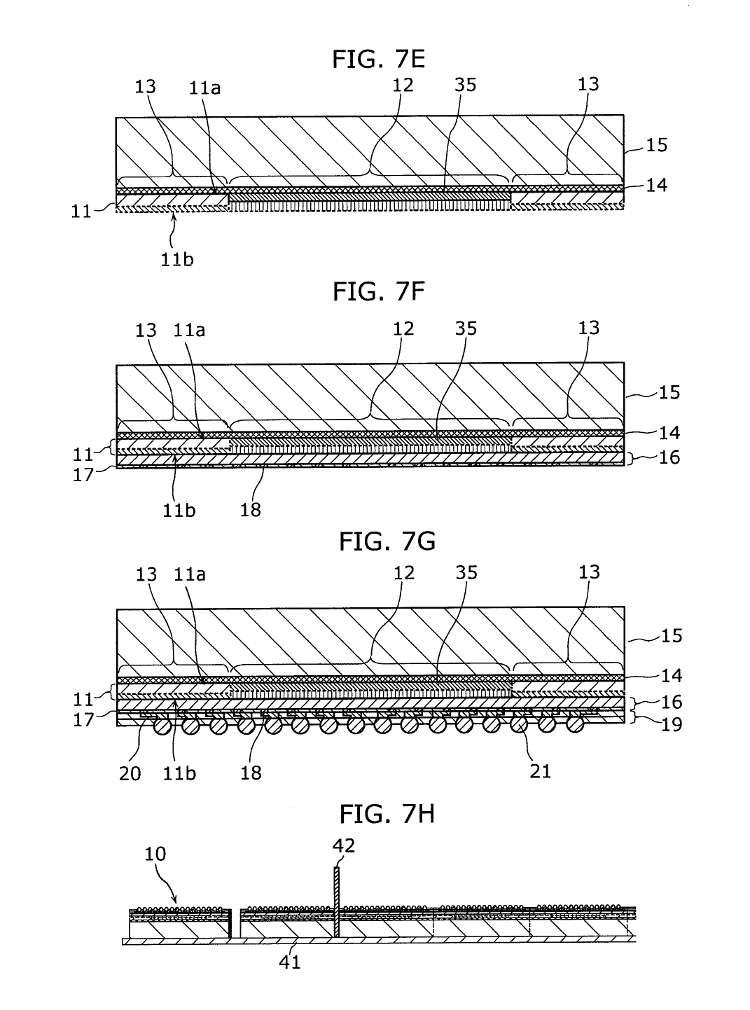

FIG. 6A to FIG. 6D and FIG. 7E to FIG. 7H are cross-sectional views showing an example of a method for fabricating the optical device according to an aspect of the present invention.

Note that for simplification, FIG. 6A to FIG. 6D and FIG. 7E to FIG. 7H mainly show cross-sectional views of essential parts constituting a unit chip. However, fabrication of the optical device in a wafer state on which unit chips are integrated is common. Note that the same numerical references are assigned to the same elements appeared in FIG. 1 and FIG. 2. For simplification, duplicate descriptions of the same elements are omitted.

First, the shallow P+ layer 27 and a well which will be a part of the pixel isolation region 26 or the like are formed in a substrate which will be formed into the semiconductor substrate layer 11, more specifically, are formed near the first surface 11a of the semiconductor substrate layer 11 (FIG. 6A).

Here, for the semiconductor substrate layer 11, a semiconductor substrate, such as a silicon wafer, having a thickness ranging from 200 to 800 μm approximately and a diameter ranging from 2 inch φ to 15 inch φ approximately, is used.

The well near the first surface 11a may be formed in the element formation process which is one of the subsequent processes; however, forming well near the first surface 11a by ion implantation from the first surface 11a side of the semiconductor substrate layer 11 is preferable since it allows excellent controllability. Further, it is preferable to perform ion implantation from the first surface 11a side of the semiconductor substrate layer 11 at least before the first surface 11a of the semiconductor substrate layer 11 is sealed by a transparent substrate.

Next, the optical component 35 that will constitute a microlens or a color filter is formed at a desired position (FIG. 6B).

Here, it is preferable that the optical component 35 is made of a material having high heat resistance. Here, the optical component 35 is made as a part of the semiconductor substrate layer 11. It may be that the optical component 35 is made of an inorganic material such as oxide silicon or silicon nitride, or a metal material, instead of forming the optical component 35 as a part of the semiconductor substrate layer 11.

Next, the adhesive layer 14 is formed on the first surface 11a of the semiconductor substrate layer 11, and the first surface 11a of the semiconductor substrate layer 11 is sealed with the optically transparent substrate 15 via the formed adhesive layer 14 (FIG. 6C).

Here, it is preferable to bond the optically transparent substrate 15, such as a glass substrate which is a high heat resistant material, to the semiconductor substrate layer 11, with the adhesive layer 14 such as an oxide silicon film which is a high heat resistant material.

As shown in FIG. 6B, since the optical component 35 is formed in the process proceeding to FIG. 6C, the optically transparent substrate 15 does not need to be separated in the process subsequent to FIG. 6C. Therefore, for the adhesive layer 14, such a material can be used that provides strong bonding between the optically transparent substrate 15 and the substrate which will be formed into the semiconductor substrate layer 11.

Next, with the optically transparent substrate 15 as a support substrate, the semiconductor substrate layer 11 is thinned from the second surface 11b side to the thickness of ranging from 5 to 15 μm approximately.

Here, for the thinning process, CMP or the like is generally used. It is preferable that soft etching or the like is performed in finishing the thinning process to eliminate damages such as lattice defect generated in CMP.

Subsequently, at desired positions in the optical element integrated region 12 and the peripheral circuit region 13 of the semiconductor substrate layer 11, elements such as wells, optical elements, and transistors, are formed from the second surface 11b side of the semiconductor substrate layer 11 (FIG. 7E).

Next, the interconnect layer 16 is formed on the second surface 11b of the semiconductor substrate layer 11 (FIG. 7F).

The interconnect layer 16 is made of one or more insulating layers including conductive materials electrically connected with the elements formed in the semiconductor substrate layer 11. On the surface layer of the insulating layers, the protective film 17 made of one or more insulating films and having the electrode pads 18 that are exposed is formed.

In the interconnect layer formation process, it is preferable to simultaneously form the light blocking structure at the second surface 11b side of the semiconductor substrate layer 11, that is, in the region of the interconnect layer 16 which corresponds to the optical element integrated region 12.

With the fabricating method described above, it is possible to form the optical device 10.

As described, in the fabricating method according to an aspect of the present invention, elements and interconnects are formed after the thinning process; and thus, influences associated with damages generated in the processes can be reduced.

Further, since thinning is performed while the optically transparent substrate 15 is serving as a support substrate, the support substrate does not need to be separated. Further, the electrode pads 18 are also exposed; and thus, processes can be simplified.

Further, since the electrode pads 18 are exposed, probe testing can also be performed at a wafer level.

Further, it is preferable that the interconnect layer 19 is formed on the interconnect layer 16, and the external terminals 21 are deposited on the top surface of the second surface 11b side (in a downwards direction in the figure) of the optical device 10 (FIG. 7G).

Here, the interconnect layer 19 has, in a stress relief layer made of one or more layers, conductive materials 20 which electrically connect the electrode pads 18 and the external terminals 21.

Accordingly, the intervening stress relief layer alleviates the influences to the properties of the packaging stress. Thus, the electrode pads 18 and the external terminals 21 can be deposited at desired positions within a unit chip. This increases flexibility in design, which is effective in reduction of interconnection resistance or size.

Further, the optical device 10 formed through the above wafer processes, is separated into pieces using, for example, a method in which the top surface of the optically transparent substrate 15 is bonded to a dicing sheet 41 and diced along the scribe lines between unit chips by a cutting blade 42 (FIG. 7H).

In such a manner, the optical device 10 according to an aspect of the present invention is formed and separated into pieces.

Next, a variation example of implementation of the optical device 10 according to an aspect of the present invention is described.

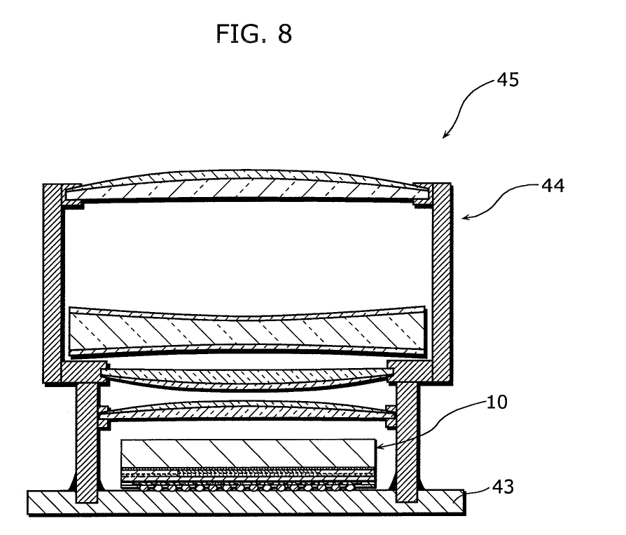

FIG. 8 is a cross-sectional view showing an example of an implementation of the optical device according to an aspect of the present invention. FIG. 8 shows a lens unit 45 including the optical device 10, as an implementation example of the optical device 10.

The lens unit 45 shown in FIG. 8 includes the optical device 10 which is packaged on the wiring board 43, and a lens tube 44 at a desired position.

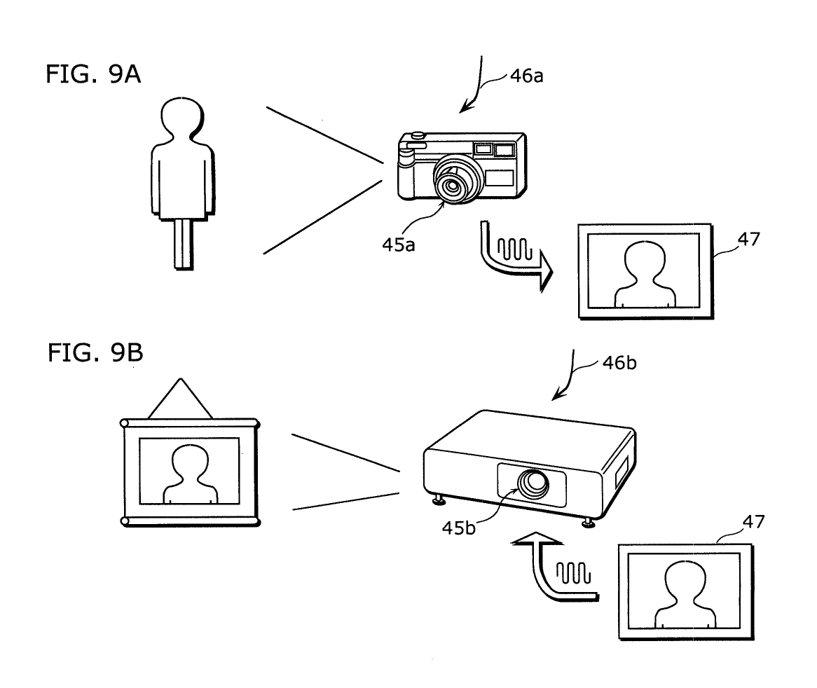

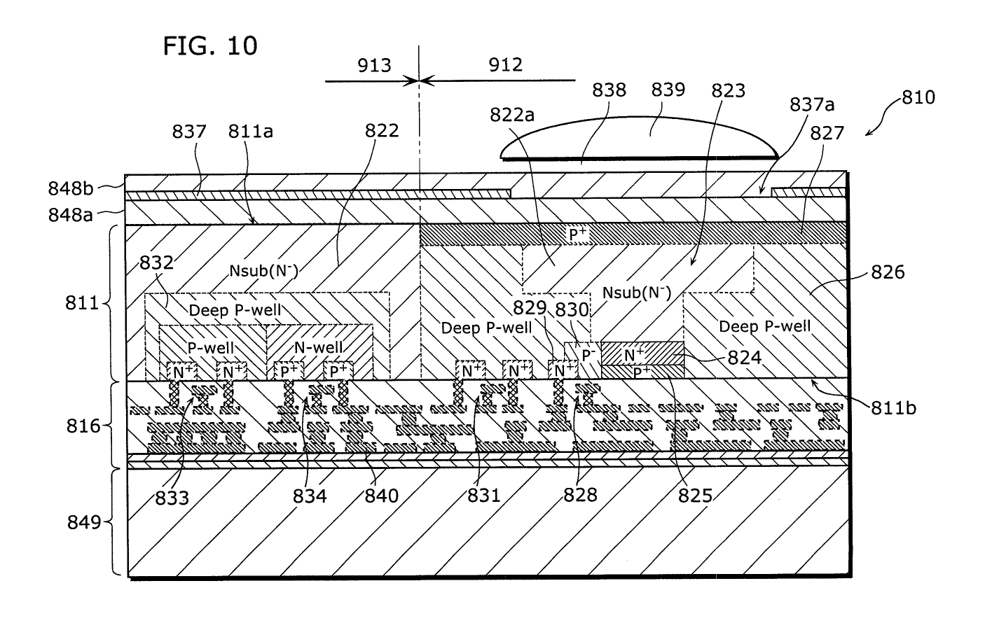

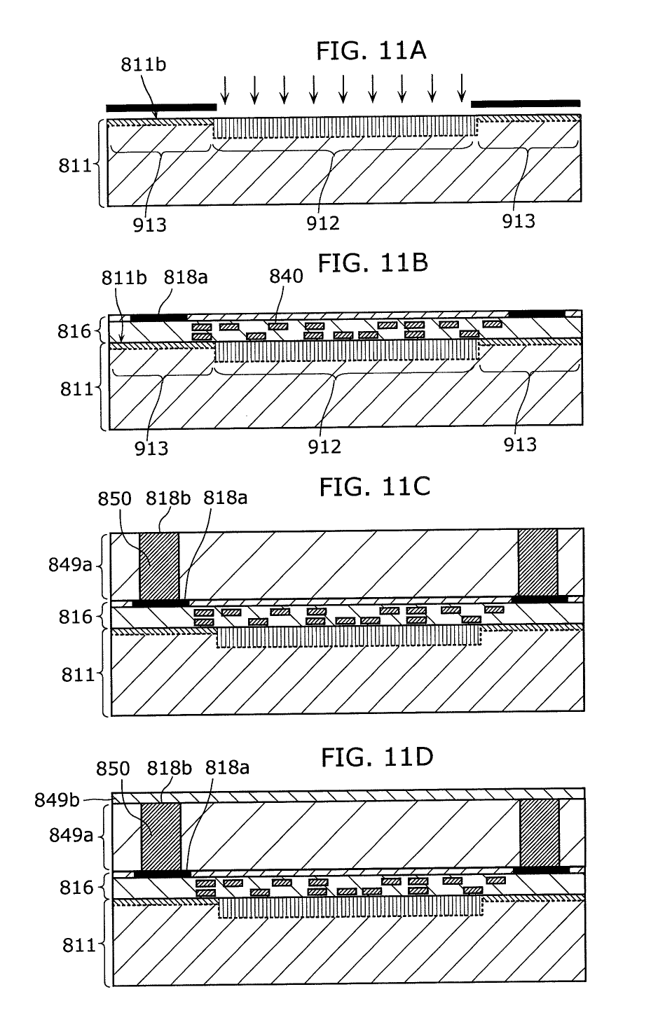

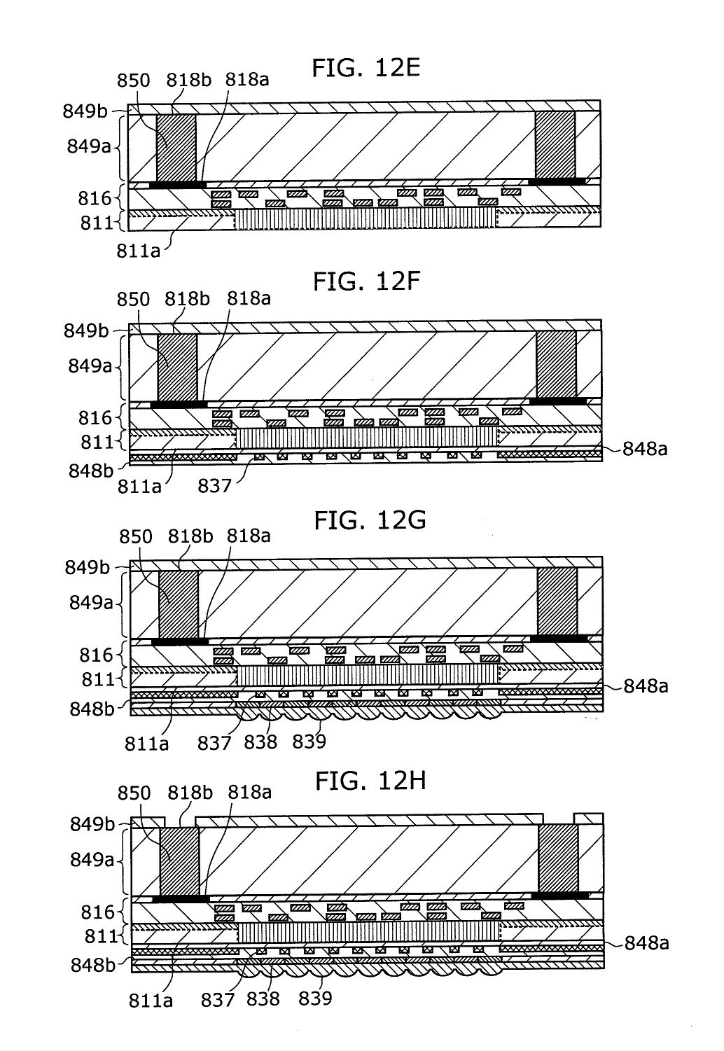

FIG. 9A and FIG. 9B are schematic diagrams showing an example of a system including the optical device according to an aspect of the present invention.

FIG. 9A is a schematic diagram showing a system including a light-receiving optical device 10 as an implementation example of the optical device 10.

An optical equipment 46a includes a unit 45a having the light-receiving optical device 10. The optical equipment 46a performs photoelectric conversion and signal processing on incident light, and converts the incident light into data 47 such as an image. Here, examples of the light-receiving optical device 10 include an imaging element and a photo IC. Such light-receiving optical device 10 is embedded into the optical equipment such as a camera, a camcorder, a camera phone, and an optical sensor.

FIG. 9B is a schematic diagram showing a system of a light-emitting optical device.

An optical equipment 46b includes a unit 45b having a light-emitting optical device. The optical equipment 46b performs photoelectric conversion and signal processing on the data 47 such as an image, and projects the data as an optical signal.

Here, examples of the light-emitting optical device include an LED and a laser. Such a light-emitting optical device is embedded into a display device, such as a projector and a monitor, and an optical equipment, such as an optical disc drive and a pointer.

As described, it is possible for the optical device 10 according to an aspect of the present invention to achieve a device structure having an excellent optical properties; and thus, the optical device 10 can be applied to digital optical equipments, such as a digital still camera, a camera phone, and a camcorder, which require reduction in size and thickness, and a high functionality.

As well as achieving the device structure with excellent optical properties, improving reliability and simplification of the processes in the fabricating process are possible. In other words, according to an aspect of the present invention, it is possible to achieve an optical device in which reliability of the optical properties are improved with simple processes, and a fabricating method thereof.

Although only an exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

The present invention can be used for optical devices and a fabricating method for the optical devices, and particularly, can be used for the optical devices and the fabricating method for the optical devices which are used for digital optical equipment, such as digital still cameras, cameras for mobile phones, camcorders, which require reduction in size and thickness, and a high functionality. Further, the optical device according to an aspect of the present invention can also be used for medical equipment, and is widely applicable to various equipment and apparatus having digital video and image processing function and other optical system.

What is claimed is:

1. An optical device comprising:
a semiconductor substrate layer including a plurality of elements;
at least one optical component formed at a first principal surface side of said semiconductor substrate layer; and
an interconnect layer formed on a second principal surface of said semiconductor substrate layer and including a conductive material, the second principal surface being an opposite side of the first principal surface side;
wherein, in said semiconductor substrate layer, (i) a photoelectric conversion element region is formed at a position corresponding to said at least one optical component such that said photoelectric conversion element region extends from a second principal surface side toward a first principal surface of said semiconductor substrate layer, and (ii) at least one element among said plurality of elements is formed near the second principal surface,
at least a part of said at least one optical component is formed as a part of said semiconductor substrate layer, and
said interconnect layer includes said conductive material electrically connected to said photoelectric conversion element region and said at least one element.

2. The optical device according to claim 1,
wherein said at least one optical component is a lens having a curved surface which corresponds to a desired wavelength.

3. The optical device according to claim 1,
wherein said at least one optical component is a color filter formed by introducing an ionic group so that the color filter corresponds to a desired wavelength.

4. The optical device according to claim 1,
wherein said at least one optical component is a color filter in which a minute level difference from the first principal surface is formed, and a thin layer is formed in a space formed by the minute level difference so that the color filter corresponds to a desired wavelength.

5. The optical device according to claim 1,
wherein said at least one optical component is a lens formed by introducing an ionic group corresponding to a desired wavelength so that parabolic concentration gradient is established in a concentric pattern.

6. The optical device according to claim 1,
wherein said at least one optical component is a color filter having an uneven surface on which minute recesses are formed at spaced intervals so that the color filter corresponds to a desired wavelength.

7. The optical device according to claim 1,
wherein said at least one optical component is a lens having an uneven surface on which minute recesses are formed at spaced intervals in a concentric pattern so that the lens corresponds to a desired wavelength, and
a width of the recesses and the spaced intervals is narrower as the recesses and the spaced intervals are farther outward from a center of the concentric pattern.

8. The optical device according to claim 1,
wherein said at least one optical component is a lens having an uneven surface on which minute recesses are formed at spaced intervals in a concentric pattern so that the lens corresponds to a desired wavelength, and
a height of the recesses is smaller as the recesses are farther outward from a center of the concentric pattern.

9. The optical device according to claim 1, further comprising
an optical element integrated region in which said photoelectric conversion element region and said at least one element are integrated,
wherein a trench is formed in said semiconductor substrate layer at a position closer to the first principal surface, the trench blocking light in a boundary region between adjacent ones of said at least one optical component in said optical element integrated region.

10. The optical device according to claim 1, further comprising
a light blocking structure formed in at least a region of said interconnect layer corresponding to each of said at least one optical component.

11. The optical device according to claim 10, further comprising
an optical element integrated region in which said photoelectric conversion element region and said at least one element are integrated,
wherein said light blocking structure is made of a light blocking film corresponding to said optical element integrated region or to each of regions obtained by horizontally dividing said optical element integrated region.

12. The optical device according to claim 10,
wherein said light blocking structure is made of a structural material identical to a structural material of said conductive material.

13. The optical device according to claim 10,
wherein said light blocking structure is made of a light blocking film formed at a position corresponding to said photoelectric conversion element region, the light blocking film having an occupied area equal to or larger than an occupied area of said photoelectric conversion region in a horizontal direction.

14. The optical device according to claim 10,
wherein said light blocking structure is made of a first light blocking film and a second light blocking film, the first light blocking film being formed at a position corresponding to the photoelectric conversion element region such that an occupied area of the first light blocking film is approximately equal to an occupied area of the photoelectric conversion element region in a horizontal direction, the second light blocking film being formed above a rim of the first light blocking film,
said interconnect layer has a multilayer interconnect structure in which interlayer films are laminated,
the second light blocking film is formed, among the interlayer films, in an interlayer film different from an interlayer film in which the first light blocking film is formed, and
the first light blocking film and the second light blocking film are formed such that the rim of the first light blocking film overlaps a part of the second light blocking film in a positional relationship vertical to the interlayer films.

15. The optical device according to claim 10,
wherein said interconnect layer has a multilayer interconnect structure in which interlayer films are laminated,
said light blocking structure is made of first light blocking films and second light blocking films, the first light blocking films being formed, among the interlayer films, in an interlayer film different from an interlayer film in which the second light blocking films are formed such that a rim of each of the first light blocking films overlap a part of each of the second light blocking films at a position corresponding to the photoelectric conversion element in a positional relationship vertical to the interlayer films, and
an occupied area of each of the first light blocking films and each of the second light blocking films is smaller than an occupied area of the photoelectric conversion element in the horizontal direction in the interlayer films.

16. The optical device according to claim 10,
wherein said interconnect layer includes one or more structural films laminated, and
at least one of said one or more structural films in the light blocking structure is made of a colored material.

17. A method for fabricating an optical device, the optical device including:
a semiconductor substrate layer including a plurality of elements; and
an interconnect layer formed on a second principal surface of the semiconductor substrate layer and including a conductive material, the second principal surface being an opposite side to a first principal surface side;
wherein, in the semiconductor substrate layer, (i) a photoelectric conversion element region is formed such that the photoelectric conversion element region extends from a second principal surface side toward a first principal surface of the semiconductor substrate layer, and (ii) at least one element among the plurality of elements is formed near the second principal surface, and
the interconnect layer includes the conductive material electrically connected to the photoelectric conversion element region and the at least one element, said method comprising:
forming an adhesive layer on a first principal surface of a substrate, and forming a support substrate which supports the substrate via the adhesive layer, the substrate being made of a semiconductor and serving as a base material for the semiconductor substrate layer;
forming the semiconductor substrate layer; and
forming the interconnect layer including the conductive material on the second principal surface of the semiconductor substrate layer.

18. The method for fabricating the optical device according to claim 17, further comprising:
forming at least one optical component at the first principal surface side of the substrate before forming the support substrate,
wherein said forming the semiconductor substrate layer further includes, at a position corresponding to each of the at least one optical component: forming the photoelectric conversion element region extending from the second principal surface side to the first principal surface of the semiconductor substrate layer; and forming the at least one element near the second principal surface of the semiconductor substrate layer,
in said forming the interconnect layer, the conductive material is formed so as to be electrically connected to the photoelectric conversion element region and the at least one elements, and
in said forming the at least one optical component, at least a part of the at least one optical component is formed as a part of the semiconductor substrate layer.

19. The method for fabricating the optical device according to claim 17,
wherein said forming the semiconductor substrate layer includes a thinning process in which a material from the second principal surface of the substrate is removed so that the substrate is thinned to a desired thickness, the second principal surface being opposite to the first principal surface of the substrate;
said thinning process further includes:
thinning the substrate by polishing the second principal surface of the substrate using an abrasive; and
removing a layer of the second principal surface of the substrate which is damaged through polishing, by a soft etching on a surface which has been polished in said thinning the substrate, so as to expose the second principal surface of the semiconductor substrate layer.

20. The method for fabricating the optical device according to claim 17, further comprising
forming a well within the substrate and near the first principal surface of the substrate from the first principal surface side of the substrate, before forming the support substrate.
